(19) United States
(12) Patent Application Publication
(10) Pub. No.: US 2016/0155874 A1
(43) Pub. Date: Jun. 2, 2016

(54) SOLAR MODULE WITH AN ELECTRICALLY INSULATED MODULE SUPPORT AND METHOD FOR PRODUCTION THEREOF

(71) Applicant: SAINT-GOBAIN GLASS FRANCE, Courbevoie (FR)

(72) Inventors: Peter BOROWSKI, Munich (DE); Oliver SCHNEIDER, Würzburg (DE)

(21) Appl. No.: 14/903,491

(22) PCT Filed: Jul. 10, 2014
(86) PCT No.: PCT/EP2014/064826

§ 371 Date: Jan. 7, 2016

(30) Foreign Application Priority Data
Jul. 10, 2013 (EP) 13175859.1

(51) Int. Cl. H01L 31/048; H01L 31/049

(52) U.S. Cl. CPC H01L 31/0481; H01L 31/049

(57) ABSTRACT

The invention describes a solar module (1), comprising at least:
a substrate (2) and a cover layer (30), between which a layer structure (23) for forming solar cells (31) is arranged, and
on a substrate surface (3) facing away from the layer structure (23), at least one module support (4) for stiffening and/or supporting mounting of the solar module (1), which has at least one adhesive surface (19), which is bonded to the substrate surface (3) via at least one adhesive layer (20), wherein the adhesive layer (20) contains a hardened, electrically highly-insulating adhesive (35).

The invention relates to a solar module with an electrically insulated module support as well as a method for its production.

Photovoltaic layer systems for the direct conversion of sunlight into electrical energy are well known. They are commonly referred to as “solar cells”, with the term “thin-film solar cells” referring to layer systems with thicknesses of only a few microns that require (carrier) substrates for adequate mechanical stability. Known substrates include inorganic glass, plastics (polymers), or metals, in particular metal alloys, and can, depending on the respective layer thickness and the specific material properties, be implemented as rigid plates or flexible films.

In view of the technological handling quality and efficiency, thin-film solar cells with a semiconductor layer of amorphous, micromorphous, or polycrystalline silicon, cadmium telluride (CdTe), gallium-arsenide (GaAs), or a chalcopyrite compound, in particular copper-indium/gallium-disulfur/diselenide, abbreviated by the formula CuF(In,Ga)(S,Se)2, have proved advantageous. In particular, copper-indium-diselenide (CulnSe2 or CIS) is distinguished by a particularly high absorption coefficient due to its band gap adapted to the spectrum of sunlight.

Typically, with individual solar cells, it is only possible to obtain voltage levels of less than 1 volt. In order to obtain a technically useful output voltage, many solar cells are connected to one another in series in a solar module. Here, thin-film solar modules offer the particular advantage that the solar cells can already be connected in an integrated form during production of the films. Thin-film solar modules have already been described many times in the patent literature. Reference is made merely by way of example to DE 4 324 318 Cl and EP 2 200 097 A1.

In practice, solar modules are mounted on the roofs of buildings (“on-roof mounting”) or form a part of the roof cladding (“in-roof mounting”). It is also known to use solar modules as facade or wall elements, in particular in the form of freestanding or self-supporting (carrier-free) glass structures.

The roof mounting of solar modules is usually done parallel to the roof on a module holder anchored on the roof or on a roof substructure. Such a module holder usually includes a rail system of parallel support rails, for example, aluminum rails, that are fastened by means of steel anchors on tile roofs or screws on corrugated sheet roofs or trapezoidal sheet metal roofs.

It is common practice to provide the solar module with a module frame made of aluminum that effects, on the one hand, mechanical reinforcement and can, on the other, serve for the mounting of the solar module on the module holder.

Recently, frameless solar modules that have reduced module weight and can be manufactured with reduced production costs have increasingly been produced. Usually, frameless solar modules are provided on their back side with module supports made of steel or aluminum that are adhesively bonded to the back side of module. Like the module frame, the module supports act reinforcingly and can serve for attaching the solar module on the module holder. In both cases, the module supports are frequently referred to as reinforcement struts or as “backrails”. In the patent literature, backrails are described, for example, in DE 10 2009057937 A1 and U.S. 2009/0205703 A1.

It is known that due to different electrical potentials between the ground potential of the immediate surroundings of the solar module and the photovoltaic layer structure, a high electrical system voltage of as much as 1500 V develops. Typically, grounding of the module support requires that the surroundings of the solar module to be at ground potential. The high system voltage results in high electrical field strengths between the module supports and the photovoltaic layer structure. Electrical transients can arise from this; or ions, such as sodium ions, can drift out of the glass into the thin layers of the photovoltaic layer structures or out of them. Corrosion or delamination of the photovoltaic cells results in permanent (potential-induced) degradation of performance or in the failure of the solar modules.

To feed electrical energy into the public supply network, photovoltaic systems require a circuit of solar modules and inverters to convert DC voltage into AC voltage.

From DE 10 2007 050 554 A1, photovoltaic systems with a rise in potential to reduce the degradation of performance during long-term use are known. The potential of the positive terminal of the circuit of solar modules is shifted in the inverter relative to the ground potential such that no uncontrolled electrical discharges from the solar module to ground occur.

Also known are inverters for photovoltaic systems that separate the solar modules galvanically from the potential to the ground via an isolating transformer to prevent uncontrolled discharges from the photovoltaic system to the ground. However, that requires costly use of inverters adapted to the solar modules, which inverters have low electrical efficiency.

DE 10 2009 044 142 A1 discloses a thin-film component and, for example, a solar module on glass with an electrically conductive protection device. Electrical discharges and/or the drift of ions from the glass pane caused by an electrical field are shifted from the functional layer structure to the electrically conductive protection device. The introduction of the electrically conductive protection device as an additional electrical component renders the production process of the thin-film component more difficult.

The object of the present invention is to advantageously improve a solar module with module supports (backrails) that is protected against potential-induced performance degradation independently of inverters and additional electrical components.

This and other objects are accomplished according to the proposal of the invention by a solar module as well as a method for producing a solar module with the characteristics of the coordinated claims. Advantageous embodiments of the invention are indicated by the characteristics of the subclaims.

According to the invention, a solar module is presented, which has a substrate and a cover layer, between which a layer structure for forming solar cells is situated. The substrate and the cover layer are made, for example, of inorganic glass, polymers, or metal alloys, and are, for example, implemented as rigid plates that are bonded to each other in a so-called laminated pane structure.

The solar module is preferably a thin-film solar module with thin-film solar cells connected in series preferably in an integrated form. Typically, the layer structure comprises a back electrode layer, a front electrode layer, as well as an absorber. Preferably, the absorber comprises a semiconductor layer made of a chalcopyrite compound, which can be, for example, a semiconductor from the group copper-indium/gallium disulfur/diselenide (Cu(In,Ga)(S,Se)2), for example, copper-indium-diselenide (CulnSe2 or CIS) or related compounds.

At least one module support for stiffening and/or supporting mounting of the solar module on a stationarily anchored module holder, such as a rail system, is fastened by adhesive bonding on the back substrate surface facing away from the layer structure. The module support preferably extends along the longitudinal sides of a rectangular (viewed from above) solar module.

In an advantageous embodiment, the solar module according to the invention has two or four module supports. This makes it possible to achieve secure attachment of the solar module with good load distribution (for example, wind load) and low material outlay.

As a rule, the module support is made of a different material than the, for example, glassy (support) substrate, typically being made of a metallic material, for example, aluminum or steel. For attachment on the substrate, the module support has at least one adhesive surface, which is adhesively bonded to the back substrate surface via an adhesive layer made of a hardened adhesive.

It is essential here that the adhesive layer contains or is made of an adhesive that is electrically highly-insulating, at least in a hardened state. The advantageous effect of the electrically highly-insulating adhesive can be understood in a simple model by the fact that a diffusion of foreign atoms out of the substrate into the layer structure is clearly reduced or virtually completely avoided by means of the electrically highly-insulating adhesive. This is true even with high voltage differences between the module support and the layer structure. Consequently, only very little or no potential-induced performance degradation of the solar module occurs.

In an advantageous embodiment of the solar module according to the invention, the adhesive has a specific resistance of ≧1500 GOhm*cm, preferably >4000 GOhm*cm, and particularly preferably of 5000 GOhm*cm to 15000 GOhm*cm. Here, it is particularly advantageous if the adhesive has this specific resistance over its complete range of use, i.e., up to 1000 V voltage difference between layer structure and module support, at up to 95° C., and at up to 85% relative humidity. Such electrically highly-insulating adhesives isolate the module support from the substrate and the photovoltaic layer structure particularly beneficially and prevent a potential-induced performance degradation particularly effectively.

Advantageous adhesives according to the invention contain silicone adhesives, polyurethanes, (poly-)acrylates, or epoxy resins. Particularly advantageous adhesives according to the invention contain single component or two component silicone adhesives. Such adhesives are particularly well-suited, since they have the electrically highly-insulating characteristics according to the invention as well as good processability and adequate strength and resistance to weathering.

In another advantageous embodiment of a solar module according to the invention, the thickness d of the adhesive layer, and in particular the minimum thickness of the adhesive layer, is from 0.5 mm to 10 mm, preferably 1 mm to 3 mm, and particularly preferably of 1.5 mm to 2.5 mm. Such thicknesses d isolate the module support from the layer structure particularly beneficially and prevent a potential-induced performance degradation particularly effectively. In another advantageous embodiment of a solar module according to the invention, the adhesive surface is from 5% to 20% and preferably from 5% to 10% of the substrate surface. This has the particular advantage that the electrical current flow, which can cause sodium migration, remains limited to a small area.

It has been demonstrated that the potential-induced performance degradation depends in particular on the voltage difference between the layer structure and the module support. The reduction in performance degradation according to the invention is more effective the greater the maximum voltage difference. It is particularly advantageous when the maximum voltage difference is greater than or equal to 900 V, preferably from 900 V to 2000 V, and particularly preferably from 1400 V to 1600 V.

In an advantageous embodiment of a solar module according to the invention, the layer structure is arranged on the substrate and bonded to the cover layer via an intermediate layer. With this so-called substrate configuration, the potential-induced performance degradation with solar modules according to the prior art without electrically highly-insulating adhesive is particularly high, due to the spatial proximity of the photovoltaic layer structure to the module support and the thus increased electrical field strengths. Surprisingly, through the use of an electrically highly-insulating adhesive, the potential-induced performance degradation can be particularly effectively reduced.

In an advantageous embodiment of a solar module according to the invention, the substrate contains or is made of glass, preferably of soda lime glass, particularly preferably with a minimum content of 11 wt. % Na2O. In a simple model, the potential-induced performance degradation can be understood by the migration of sodium ions out of the substrate into the photovoltaic layer structure. As a result of the altered sodium doping of the layer structure deviating from the optimum content, the performance of the solar module decreases. By means of the electrically highly-insulating adhesive, the electrical field strength and thus also the migration of foreign ions, such as sodium ions, out of the substrate into the layer structure or within the layer structure is reduced and the performance of the solar module is retained.

In an advantageous embodiment of the solar module according to the invention, the solar module has no metallic frame that serves for stabilization or for attachment. Such frameless solar modules, also referred to as laminates, are provided with grounding only via the module support. Since the module supports are arranged very near and, over a relatively large area, below the photovoltaic layer structure, the potential-induced performance degradation is particularly great with solar modules according to the prior art without electrically highly-insulating adhesive. The use according to the invention of an electrically highly-insulating adhesive is particularly effective and prevents or reduces performance degradation particularly well.

It has been demonstrated that the bonding of module supports onto the substrate by hardening adhesives in industrial series production is often associated with a certain variability with regard to the distance between the module support and the back substrate surface. The reason for this is the plastic deformability of the (as yet) unhardened adhesive during the bonding of the module support and substrate. In an advantageous embodiment of the solar module according to the invention, the adhesive layer contains one or a plurality of spacers, which are in each case implemented for the purpose of holding the adhesive surface of the module support, while the adhesive is not yet hardened, at a pre-definable minimum distance from the back substrate surface, when the module support is delivered to the back substrate surface in order to bond the module support to the back substrate surface via the adhesive layer. Here, it is particularly advantageous for the spacers to have a specific electrical resistance of roughly the same magnitude as the electrically highly-insulating adhesive or greater.

In a particularly advantageous embodiment of the solar module according to the invention, the solar module has no frame on its outer edges, but, instead, is reinforced, stabilized, and attached only by the module support on the module back side. Such frameless solar modules are particularly simple and cost-effective to produce.

In another advantageous embodiment of the solar module according to the invention, which is implemented in the shape of a rectangle, the at least one module support extends, for example, in the form of an elongated reinforcement strut along the (module) longitudinal sides and the at least one adhesive layer is implemented in the form of an adhesive layer (adhesive bead) also extending along the (module) longitudinal sides. Since solar modules are typically moved in assembly lines of industrial series production along the longitudinal sides, a lateral shifting of spacers (in the module transverse direction) can advantageously be avoided by this measure. Movement of the spacers out of the adhesive layer due to movement of the solar modules can thus be avoided reliably and with certainty.

The invention further extends to a method for producing a solar module, in particular a thin-film solar module, which comprises the following steps:
Preparing a substrate and a cover layer, between which a layer structure for forming solar cells is situated,
Preparing at least one module support for stiffening and/or supporting mounting of the solar module,
Applying an adhesive layer made of a hardenable, electrically highly-insulating adhesive on at least one adhesive surface of the module support and/or on a substrate surface facing away from the layer structure,
Bonding the module support to the substrate surface via the at least one adhesive layer,
(Allowing) hardening of the adhesive of the adhesive layer for the adhesive attachment of the module support on the substrate.

By means of the method according to the invention, a solar module can be produced technically simply and economically, while a potential-induced performance degradation is reduced or avoided reliably and with certainty.

In a preferred embodiment of the method according to the invention, one or a plurality of spacers are introduced into the not yet hardened adhesive. The spacers are, in each case, implemented for the purpose of holding the adhesive surface at a pre-definable minimum distance from the substrate surface while the adhesive of the adhesive layer is unhardened. By this means, a solar module can be produced technically simply and economically, while ensuring that the module support is arranged on the back substrate surface at a distance pre-definable by the spacers.

From a production engineering standpoint, it can be advantageous for the spacers to be introduced into the at least one adhesive layer already applied on the adhesive surface of the module support and/or of the back substrate surface. This measure enables simple spraying of the adhesive from a conventional nozzle, without having to adapt the nozzle to the dimensions of the spacers. Preferably, the introduction of the spacers into the adhesive layer is done by blowing the spacers in pneumatically by a pressure surge, which can be realized technically in a particularly simple and economical manner. In addition, the spacers can be selectively positioned at pre-defined locations inside the adhesive layer.

The invention further extends to the use of at least one adhesive layer made of a hardenable and, in the hardened state, electrically highly-insulating adhesive for attaching a module support on a back substrate surface of a solar module, in particular a thin-film solar module, wherein the electrically highly-insulating adhesive reliably reduces or prevents the potential-induced performance degradation of the solar module.

The invention is now explained in detail with reference to an exemplary embodiment, referring to the accompanying figures. They depict:

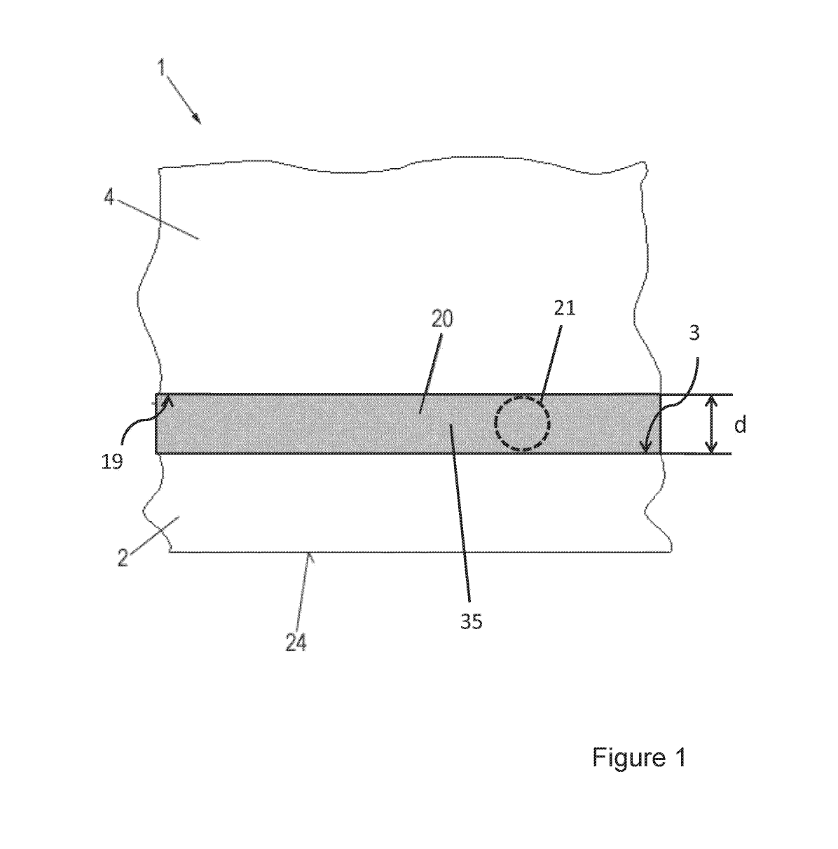

FIG. 1 using a schematic (partial) cross-sectional view, the bonding of a module support to the back substrate surface of a solar module;

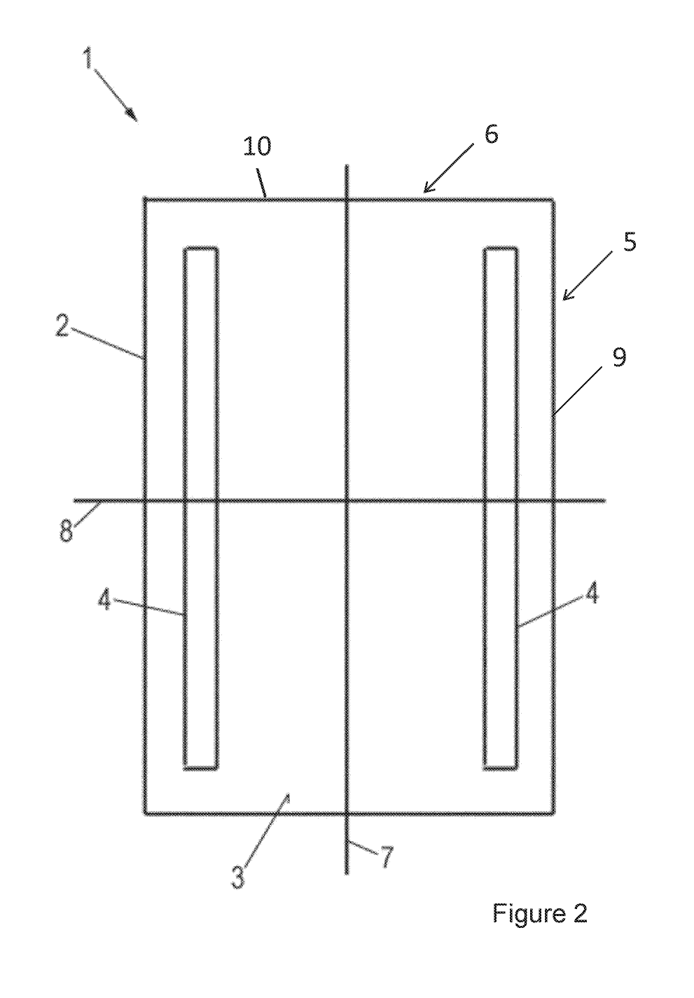

FIG. 2 a schematic plan view of the back side of the solar module of FIG. 1;

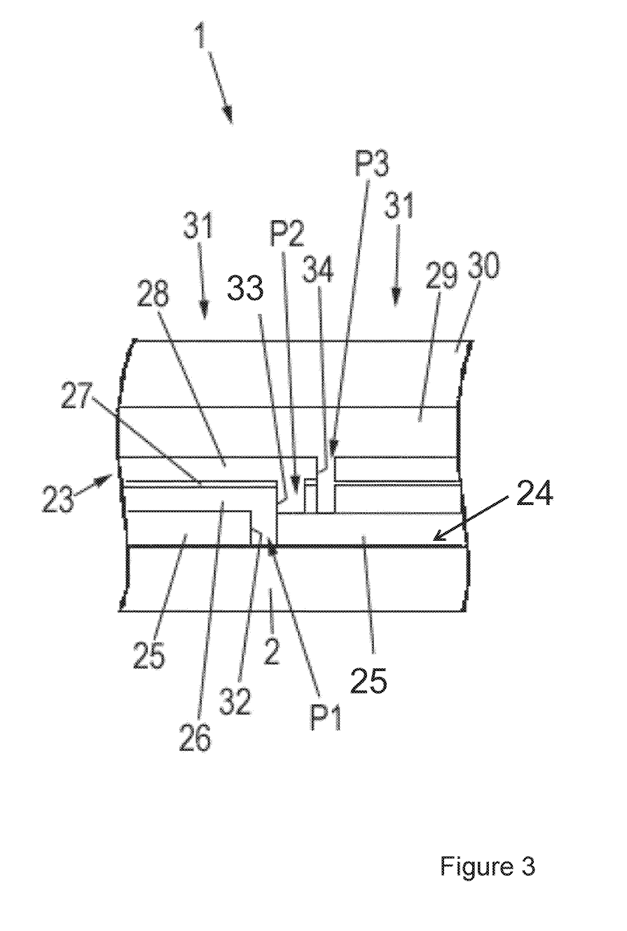

FIG. 3 a schematic cross-sectional view through the solar module of FIG. 1;

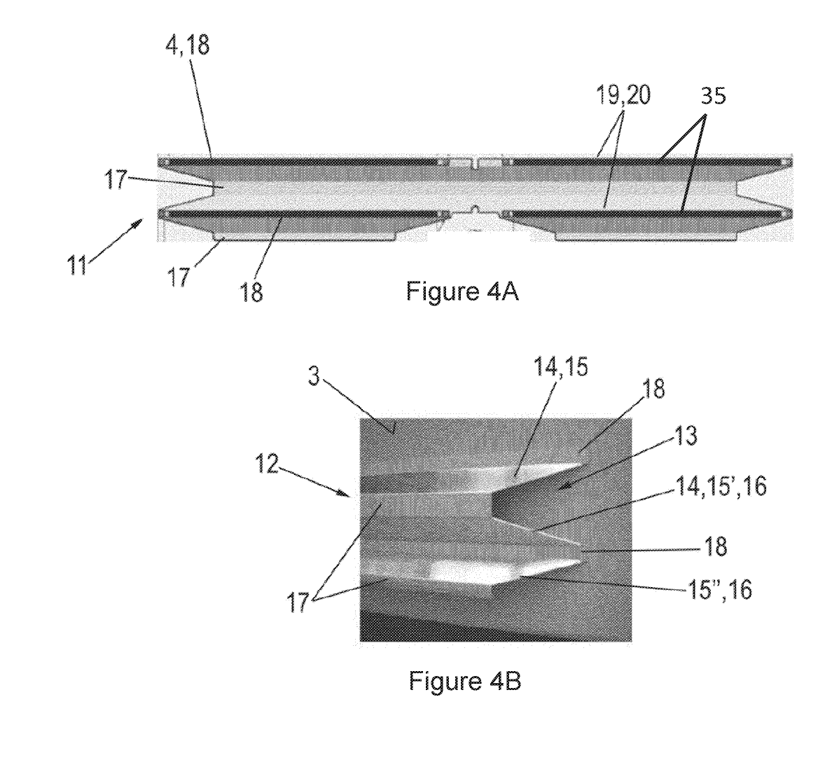

FIG. 4A-4B schematic perspective views of the module support of the solar module of FIG. 1;

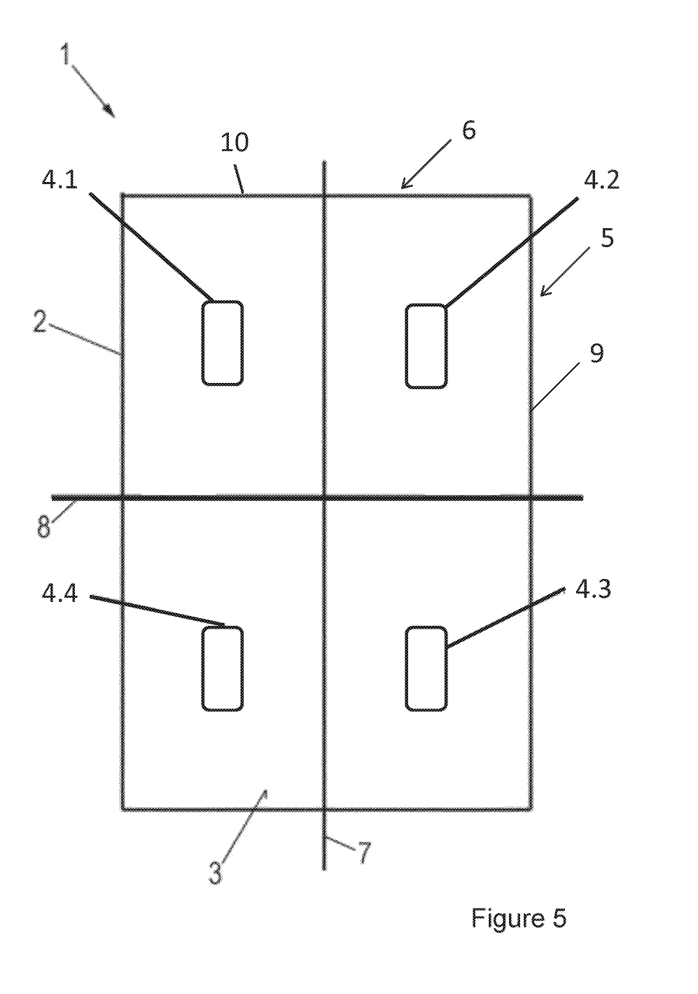

FIG. 5 a schematic plan view of the back side of an alternative solar module;

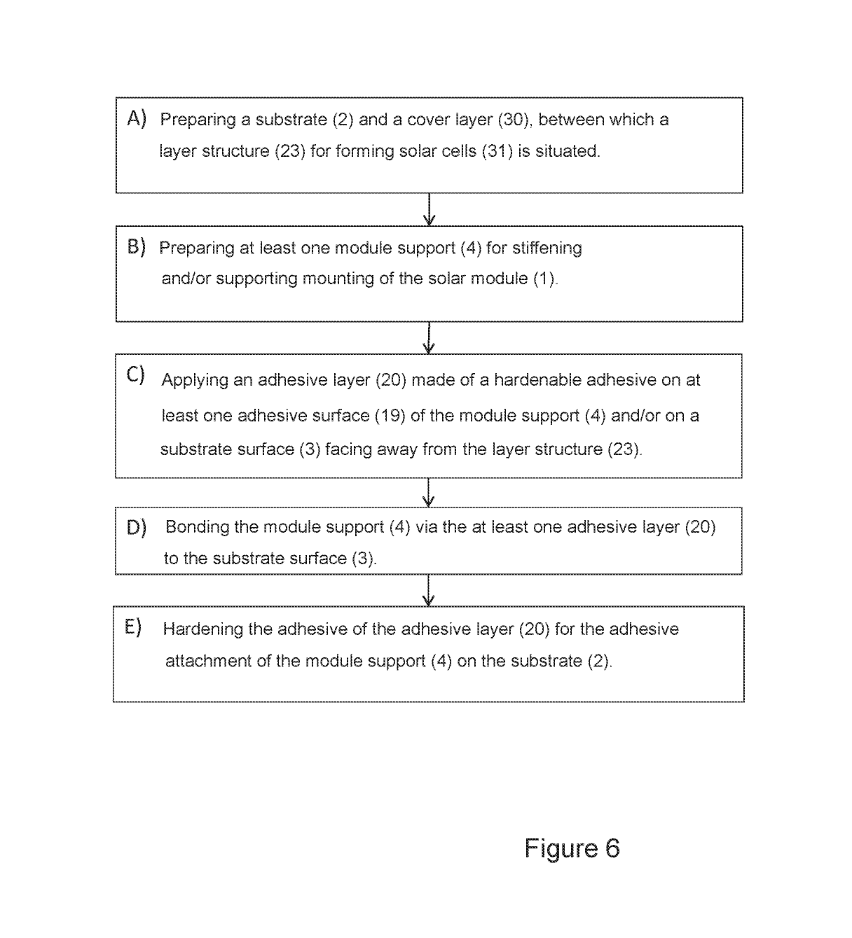

FIG. 6 a flowchart of the method according to the invention, and

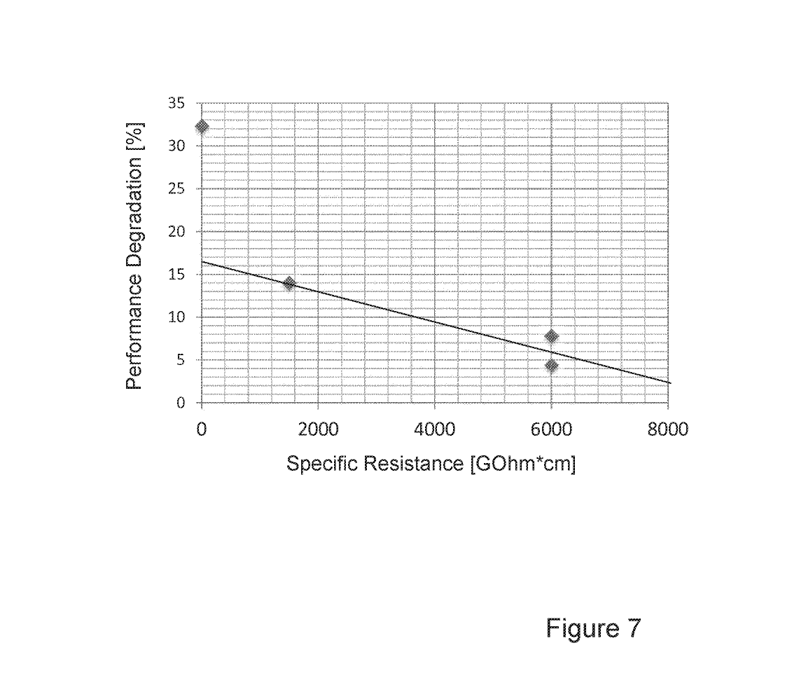

FIG. 7 a diagram of the potential-induced performance degradation as a function of the specific electrical resistance of the adhesive.

Reference is first made to FIG. 2 and FIG. 3. FIG. 2 depicts a schematic view of the module back side (“Side IV”) of a solar module 1 referenced as a whole with the reference number 1 using the example of a thin-fill solar module. As is customary, the solar module 1 is implemented in the form of a rectangular flat body (viewed from the top) with two parallel longitudinal sides 5 and transverse sides 6 perpendicular thereto. FIG. 3 depicts a cross-sectional view through the solar module 1.

As discernible in FIG. 3, the solar module 1 has a structure corresponding to the so-called substrate configuration. In other words, it has an electrically isolating (carrier) substrate 2 with a layer structure 23 made of thin layers applied thereon, which is arranged on a light-entry or front substrate surface 24 (“Side III”) of the substrate 2. The substrate 2 is made here, for example, of glass and in particular of soda lime glass, with a relatively low light transmittance, with the possibility of likewise using other isolating materials with adequate strength, as well as inert behavior relative to the process steps performed.

Specifically, the layer structure 23 comprises a back electrode layer 25 arranged on the front substrate surface 24, which layer 25 is made, for example, of an opaque metal such as molybdenum (Mo) and can, for example, be applied on the substrate 2 by vapor deposition. The back electrode layer 25 has, for example, a layer thickness of ca. 1 μm. A semiconductor layer 26 that contains a semiconductor whose band gap is preferably capable of absorbing the greatest possible fraction of sunlight is deposited on the back electrode layer 25. The semiconductor layer 26 is made, for example, of a p-conductive chalcopyrite semiconductor, for example, a compound of the group Cu(In,Ga)(S,Se)2,in particular sodium (Na)-doped copper-indium-diselenide (CInSe₂). The semiconductor layer 26 has, for example, a layer thickness, which is in the range from 1-5 μm and is, for example, ca. 2 μm. A buffer layer 27 is deposited on the semiconductor layer 26; which buffer layer 27 is made here, for example, of a single layer of cadmium sulfide (CdS) and a single layer of intrinsic zinc oxide (i-ZnO) (not shown in detail in the figures). The buffer layer 27 has, for example, a smaller layer thickness than the semiconductor layer 26. A front electrode layer 28 is applied on the buffer layer 27, for example, by vapor deposition. The front electrode layer 28 is transparent to radiation in the visible spectral range (“window layer”), to ensure only slight weakening of the incident sunlight. The transparent front electrode layer 28, which can generally be referred to as a TCO-Schicht (TCO=transparent conductive electrode), is based on a doped metal oxide, for example, n-conductive, aluminum (AD-doped zinc oxide (ZnO). The front electrode layer 28, together with the buffer layer 27 and the semiconductor layer 26, forms a heterojunction (i.e., a sequence of layers with opposing conductor type). The layer thickness of the front electrode layer 28 is, for example, ca. 300 nm.

For protection against environmental influences, an intermediate layer 29, which is made, for example, of polyvinyl butyral (PVB) or ethylene vinyl acetate (EVA) and which is adhesively bonded to a cover layer 30 transparent to sunlight, which is, for example, made of low-iron extra-white glass, is applied on the front electrode layer 28. In order to increase the overall module voltage, the module surface of the thin-film solar module 1 is divided into a large number of individual solar cells 31, which are connected to each other in series connection. For this purpose, the layer structure 23 is patterned using a suitable patterning technology, for example, laser writing or machining (e.g., drossing or scratching). For each solar cell 31, such patterning typically comprises three patterning steps, abbreviated with the acronyms P1, P2, P3. In a first patterning step P1, the back electrode layer 25 is interrupted by the creation of a first trench 32, which is done before the application of the semiconductor layer 26, such that the first trench 32 is filled by the semiconductor material of this step. In a second patterning step P2, the semiconductor layer 26 and the buffer layer 27 are interrupted by the creation of a second trench 33, which is done before the application of the front electrode layer 28, such that the second trench 33 is filled by the electrically conducting material of this layer. In a third patterning step P3, the front electrode layer 28, the buffer layer 27, and the semiconductor layer 26 are interrupted by the creation of a third trench 34, which is done before the application of the plastic layer 29, such that the third trench 34 is filled by the insulating material of this layer. Alternatively, it would be conceivable for the third trench 34 to reach all way down to the substrate 2. By means of the patterning steps P1, P2, P3 described, solar cells 31 are formed serially connected to each other. The solar module 1 has, for example, a terminal voltage of typically 60 V. By series connection of multiple solar modules 1 in a photovoltaic system—depending on the position in the serial connection—voltages between the layer structure of an individual solar module and ground potential of more than 1000 V result.

As discernible in FIG. 2, two elongated module supports 4 are attached on the back side of the module, i.e., on the back substrate surface 3 of the substrate 2, which faces away from the layer structure 23 for forming the solar cells. The module supports 4 extend in each case along the longitudinal sides 5 of the solar module 1 and are, for example, arranged on both sides of a longitudinal median plane 7 and symmetric to the median transverse plane 8 of the solar module 1 near the module longitudinal edge 9. They end in each case a short distance before the module transverse edge 10.

A mechanical reinforcement of the solar module 1 can be achieved by means of the two elongated module supports 4. On the other hand, the module supports 4 serve for mounting of the solar module 1 by attachment to a stationarily anchored module holder, which typically includes a plurality of support rails made, for example, of aluminum. The two module supports 4 are made of a metallic material, for example, aluminum or steel. Although two module sports 4 are depicted in FIG. 2, it is understood that the solar module 1 can equally have a larger or smaller number of module supports 4.

FIG. 4A and 4B depict an individual module support 4 in detail, with FIG. 4A depicting a perspective plan view of the front side 11 of the module support 4 to be bonded to the back substrate surface 3 and FIG. 4B depicting a perspective view of the face 13 and the back side 12 of the module support 4.

According to these figures, the module support 4 is implemented as a profile part and is produced, for example, from a metal plate by a metal forming process. The module support 4 can be broken down, at least theoretically, into two sections 14, 16 with a V-shaped profile. Thus, the module support 4 comprises a first V-shaped section 14 with two legs 15, 15′ positioned at an acute angle relative to each other that are connected to each other by a back strip 17. The two legs 15, 15′ are in each case connected to a front strip 18 extending along the longitudinal sides 5, which is bent laterally from the leg 15, 15′. The two front strips 18 provide adhesive surfaces 19 for attachment of the module support 4 on the substrate 2. One of the two front strips 18 is connected to another leg 15″, which is positioned at an acute angle relative to the adjacent leg 15′, by which means, together with the adjacent leg 15′, a second V-shaped section 16 is formed, which is oriented in the opposite direction from the first V-shaped section 14. Another back strip 17 is situated on this leg 15″. By means of the structure of the module support 4 with an angled profile, the solar module 1 can be very effectively stiffened.

As illustrated in FIG. 4A and 4B, an adhesive bead 20 is applied in each case on the two adhesive surfaces 19 of the module support 4, which adhesive bead 20 serves for the adhesive bonding of the module support 4 to the back substrate surface 3. The adhesive beads 20 extend substantially over the complete length of the adhesive surfaces 19. Typically, the adhesive 35 is, in the not hardened state, soft or plastically malleable and is converted by curing into a hard state, optionally elastically malleable to a certain extent, with the module support 4 fixedly bonded to the substrate 2. Reference is now made to FIG. 1, where the adhesive bonding of a module support 4 to the back substrate surface 3 of the solar module 1 is illustrated using a schematic (partial) cross-sectional representation along the longitudinal sides 5 of the solar module 1. The cross-section is cut through an adhesive bead 20 of an adhesive 35. The adhesive layer 20 is made from a hardenable or, in the bonded state, hardened electrically highly-insulating adhesive 35, which has a high specific electrical resistance of, for example, 6000 GOhm*cm. The thickness d of the adhesive layer 20 corresponds to the distance shown between the module support 4 and the substrate 2 and is, for example, 2 mm.

FIG. 1 depicts, in an optional embodiment of the adhesive layer 20, a spacer 21 in the shape of a sphere. It is understood that the adhesive layer 20 can also have a plurality of spacers 21, which can also have different, for example, rod, cuboid, or trapezoid shapes. By means of the equal diameters of the spacers 21, a minimum distance between the two adhesive surfaces 19 of the module support 4 and the back substrate surface 3 can be predefined, when the module support 4 is pressed against the substrate 2 for its adhesive bonding. The spacer 21 is made here, for example, of an elastically malleable plastic, for example, EPDM (ethylene-propylene-diene-rubber) with a Shore hardness of 85 or POM (polyoxymethylene) with a Shore hardness of 80. In order to avoid local current flows through the spacers, it is particularly advantageous for the spacers to have a specific electrical resistance on the order of the electrically highly-insulating adhesives 35 or greater. The spacers 21 are preferably harder than the non-cured adhesive 35, in order to fulfill the spacer function. They are, however, not “too hard”, so damage to the glassy substrate 2 due to local point loads can be avoided. Generally speaking, here, the hardness of the spacers 21 is less than that of the substrate 2. Moreover, the hardness of the spacers 21 corresponds at a maximum to that of the hardened adhesive, in order to avoid point loads from the spacers 21 at the time of strong force effects in practice, for example, from snow or wind pressure loads.

FIG. 5 depicts an exemplary embodiment of the back substrate surface 3 of an alternative solar module 1. As discernible in FIG. 5, four module supports 4.1, 4.2, 4.3, 4.4 are attached on the back of the module, i.e., on the back substrate surface 3 of the substrate 2, which faces away from the layer structure 23 for forming the solar cells. Through the use of module supports 4.1, 4.2, 4.3, 4.4, a secure attachment can be achieved with good load distribution and lower material outlay compared to the example from FIG. 2.

FIG. 6 depicts a flowchart of the method according to the invention for producing a solar module 1 with an electrically highly-insulating module support 4.

In experiments, the potential-induced degradation was measured under standardized test conditions. The test was done in a climate chamber over a time period of 500 hours, wherein the solar modules 1 were subjected to a temperature of 95° C. at 85% relative humidity and the solar modules 1 were cooled once a day to −40° C. The solar modules 1 were placed electrically isolated in the climate chamber. The solar modules 1 were grounded at all points provided and in the case of the solar modules M3-M6 on the module supports 4 on the back substrate side 3 of the substrate 2. The solar modules M1 and M2 served as a reference and had no bonded-on module supports 4. The solar modules M1-M6 had an area of 30 cm×30 cm. The inner layer structure 23 of the solar modules 1 corresponded to that depicted in FIG. 3 and the above-described structure of a thin-film solar module based on a chalcopyrite semiconductor.

With the solar modules M3-M6, during the test, a voltage of −1000 V was applied between the short-circuited module connections and the ground. The solar modules M1 and M2 were left without module supports 4 on the back substrate surface 3 and without voltage application for 500 hours in the climate chamber and serve as a reference.

The adhesives A and B are single-component, alkoxy-group curing silicone adhesives, with a specific resistance of 6000 GOhm*cm or 1500 GOhm*cm. Adhesive C is a sprayable single-component adhesive and sealant based on silane-modified polymers, which cross-links (cures) by reaction with moisture to form an elastic product with a specific electrical resistance of 5 GOhm*cm.

The results of the experiments are presented in Table 1 and in FIG. 7. The performance degradation indicated is the difference in performance measured on solar simulators after light soaking before and after the test based on the pretest performance.

Shown is a clear reduction of performance degradation as a function of the specific electrical resistance of the adhesive 35 with which the module supports 4 are attached on the back substrate surface 3 of the solar modules M3-M6. In the case of the adhesive A with a specific resistance of 6000 GOhm*cm, the performance degradation is 4.4% and 7.8%. In the case of the adhesive B with a specific resistance of 1500 GOhm*cm, the performance degradation is 14.0%. In the case of the adhesive C according to the prior art with a specific resistance of 5 GOhm*cm, the performance degradation is 32.3%. Thus shown is an unexpected and drastic decrease in the performance degradation for adhesives according to the invention A, B with specific resistances greater than or equal to 1500 GOhm*cm compared to adhesives C according to the prior art with specific resistance of 5 GOhm*cm. clicks a

TABLE 1
Performance Degradation As a Function of Different Adhesives

| | | Spec. | | Performance |
|---|---|---|---|---|
| | | Resistance | | Degradation |
| Solar Module | Adhesive | [GOhm * cm] | Voltage [V] | [%] |
| M1 (Reference) | Without | | 0 | 0.0 |
| M2 (Reference) | Without | | 0 | 1.8 |
| M3 | A | 6000 | −1000 | 4.4 |
| M4 | A | 6000 | −1000 | 7.8 |
| M5 | B | 1500 | −1000 | 14.0 |
| M6 | C | 5 | −1000 | 32.3 |
| | (Prior Art) | | | |

As is clear from the preceding description, the invention makes available a solar module 1 that enables simple, reliable, and economical adhesive bonding of module supports 4 for the stabilization or supporting attachment on a module holder. Through the use according to the invention of an electrically highly-insulating adhesive 35, the potential-induced degradation of the module performance is clearly reduced. This was unexpected and surprising for the person skilled in the art.

### LIST OF REFERENCE CHARACTERS

1 solar module
2 substrate
3 back substrate surface 4, 4.1, 4.2, 4.3, 4.4 module support
5 longitudinal side
6 transverse side
7 median longitudinal plane
8 median transverse plane
9 module longitudinal edge
10 module transverse edge
11 front side
12 back side
13 front face
14 first V-shaped section
15, 15′, 15″ leg
16 second V-shaped section
17 back strip
18 front strip
19 adhesive surface
20 adhesive layer
21 spacer
23 layer structure
24 front substrate surface
25 back electrode layer
26 semiconductor layer
27 buffer layer
28 front electrode layer
29 intermediate layer
30 cover layer
31 solar cell
32 first trench
33 second trench
34 third trench
35 adhesive
d thickness of the adhesive layer 20

1. Solar module (1), comprising at least
a substrate (2) and a cover layer (30), between which a layer structure (23) for forming solar cells (31) is arranged, and
on a substrate surface (3) facing away from the layer structure (23), at least one module support (4) for stiffening and/or supporting mounting of the solar module (1), which has at least one adhesive surface (19), which is bonded to the substrate surface (3) via at least one adhesive layer (20),
wherein the adhesive layer (20) contains a hardened, electrically highly-insulating adhesive (35).

2. Solar module (1) according to claim 1, wherein the adhesive (35) has a specific resistance of ≧1500 GOhm*cm, preferably >4000 GOhm*cm, particularly preferably of 5000 GOhm*cm to 15000 GOhm*cm.

3. Solar module (1) according to claim 1 or 2, wherein the adhesive (35) contains a silicone adhesive and preferably a single component or two component silicone adhesive.

4. Solar module (1) according to one of claims 1 through 3, wherein the thickness d of the adhesive layer (20) is from 0.5 mm to 10 mm, preferably 1 mm to 3 mm, and particularly preferably of 1.5 mm to 2.5 mm.

5. Solar module (1) according to one of claims 1 through 4, wherein the adhesive surface (19) is from 5% to 20% and preferably from 5% to 10% of the substrate surface (3).

6. Solar module (1) according to one of claims 1 through 5, wherein the maximum voltage difference between the layer structure (23) and the module support (4) is greater than or equal to 900 V, preferably from 900 V to 2000 V, and particularly preferably from 1400 V to 1600 V.

7. Solar module (1) according to one of claims 1 through 6, wherein the solar module (1) has no frame.

8. Solar module (1) according to one of claims 1 through 7, wherein the substrate (2) contains soda lime glass, preferably with a minimum content of 11 wt. % Na₂O.

9. Solar module (1) according to one of claims 1 through 8, wherein the layer structure (23) is arranged on the substrate (2) and is bonded to the cover layer (30) via an intermediate layer (29).

10. Solar module (1) according to one of claims 1 through 9, wherein the adhesive layer (20) contains one or a plurality of spacers (21), each of which is implemented for the purpose of holding the adhesive surface (19) of the adhesive layer (20) at a pre-definable minimum distance from the substrate surface (3) while the adhesive (35) is unhardened.

11. Method for producing a solar module (1), with the following steps:
Preparing a substrate (2) and a cover layer (30), between which a layer structure (23) for forming solar cells (31) is situated,
Preparing at least one module support (4) for stiffening and/or supporting mounting of the solar module (1),
Applying an adhesive layer (20) made of a hardenable adhesive on at least one adhesive surface (19) of the module support (4) and/or on a substrate surface (3) facing away from the layer structure (23),
Bonding the module support (4) to the substrate surface (3) via the at least one adhesive layer (20),
Hardening the adhesive of the adhesive layer (20) for the adhesive attachment of the module support (4) on the substrate (2).

12. Method according to claim 11, wherein one or a plurality of spacers (21) are introduced into the not yet hardened adhesive, wherein the spacers (21) are in each case implemented for the purpose of holding the adhesive surface (19) at a pre-definable minimum distance from the substrate surface (3) while the adhesive of the adhesive layer (20) unhardened.

13. Use of at least one adhesive layer (20) made from an adhesive (35) electrically highly-insulating in the hardened state for attaching a module support (4) on a back substrate surface (3) of a solar module (1), in particular a thin-film solar module, for reducing a potential-induced performance degradation of the solar module (1).
